(19) United States
(12) Patent Application Publication
(10) Pub. No.: US 2023/0055303 A1
(43) Pub. Date: Feb. 23, 2023

(54) PARALLEL TRIGGER PATHS IN A TEST AND MEASUREMENT INSTRUMENT

(71) Applicant: Tektronix, Inc., Beaverton, OR (US)

(72) Inventors: Joshua J. O'Brien, Aloha, OR (US); Jed H. Andrews, Aloha, OR (US)

(73) Assignee: Tektronix, Inc., Beaverton, OR (US)

(21) Appl. No.: 17/891,901

(22) Filed: Aug. 19, 2022

Related U.S. Application Data
(60) Provisional application No. 63/236,184, filed on Aug. 23, 2021.

(51) Int. Cl. G01R 13/02

(52) U.S. Cl. CPC G01R 13/0254

(57) ABSTRACT

A test and measurement instrument includes an auxiliary trigger input port for receiving an auxiliary trigger signal, a digital trigger processor for generating a digital trigger signal from the auxiliary trigger signal, an analog trigger processor for generating an analog trigger signal from the auxiliary trigger signal, a user-configurable selector coupled to the digital trigger processor and to the analog trigger processor, the user-configurable selector configured to output either the digital trigger signal or the analog trigger signal as a selected trigger output signal of the instrument. Methods of creating parallel triggers are also described.

### CROSS-REFERENCE TO RELATED APPLICATIONS

This disclosure claims benefit of U.S. Provisional Application No. 63/236,184, titled “PARALLEL TRIGGER PATHS IN A TEST AND MEASUREMENT INSTRUMENT,” filed on Aug. 23, 2021, the disclosure of which is incorporated herein by reference in its entirety.

### TECHNICAL FIELD

This disclosure relates to test and measurement instruments, and more particularly to a trigger system for a test and measurement instrument.

### BACKGROUND

Oscilloscopes and other test instruments typically include multiple input channel ports for receiving one or more signals from a device under test, an “auxiliary trigger” input port for receiving an external trigger signal, and a “trigger out” port to output a trigger signal from the first oscilloscope to an instrument or device downstream. As oscilloscopes have moved from analog trigger systems to digital trigger systems, the time delay from an event occurring at the front end of the first oscilloscope or probe to it generating a trigger out signal has increased by orders of magnitude. This time delay from the time the first auxiliary trigger is received until the first oscilloscope generates the trigger out signal causes issues for users who desire to use the trigger out signal to drive another capture instrument, especially for those events having a short capture time window. In other words, if a cascaded pair of instruments are coupled to the same device under test (DUT), and the second instrument relies on the trigger out signal of the first instrument to trigger a data or signal capture on the second instrument, the time delay caused by processing the trigger out signal through the first instrument may cause the second instrument to completely miss the event of interest. Specific examples of this problem include having an oscilloscope as the first capturing instrument cascaded with a spectrum analyzer or a camera. By the time the trigger out signal leaves the oscilloscope, the event of interest may have passed, and can no longer be captured by these secondary acquisition instruments. This is especially true for events of interest that have short durations.

The long latency of a digital trigger system is also a problem for customers who use several oscilloscopes chained together. Typically, these customers provide a trigger into the auxiliary trigger input of the first oscilloscope and then drive the trigger out of that first oscilloscope to the auxiliary trigger in of the next oscilloscope. The trigger out of the second oscilloscope is driven to the auxiliary trigger in of a third oscilloscope. This daisy chaining of auxiliary trigger signals can be extended to a near unlimited number of oscilloscopes. The real-world limit, however, to the number of oscilloscopes that can be supported in these chains is the maximum capture time of the oscilloscope minus the needed capture time, divided by the latency of the trigger. If the trigger signals for the cascaded devices are received in adequate time for all of the cascaded devices to acquire the event of interest, post processing of the acquired signals in the cascaded devices can align the captures and effectively back out the latency. Even in cascaded systems that do receive the cascaded trigger signals within the event of interest, higher triggering latency requires longer post processing since the amount of unused acquisition memory scales with the latency. In other words, cascaded test systems store voluminous amounts of data as the delayed trigger signal cascades through the system. And there is no present solution to reduce the latency of cascaded trigger signals to minimize the possibility of cascaded measurement devices missing the event windows entirely.

Embodiments of this disclosure address these and other limitations of existing devices.

### BRIEF DESCRIPTION OF THE DRAWINGS

FIG. 1 is a functional block diagram of a test and measurement instrument, such as an oscilloscope, having parallel trigger paths, according to embodiments of the disclosure.

FIG. 2 is functional block diagram illustrating another representation of an instrument having parallel trigger paths, according to embodiments of the disclosure.

FIG. 3 is a functional block diagram of a test and measurement instrument including an analog trigger conditioning circuit 380 in an analog trigger path, according to embodiments of the disclosure.

FIG. 4 is a functional block diagram of a test and measurement instrument including an analog trigger conditioning circuit as well as a second triggering unit that uses an acquired input signal condition to generate an input signal trigger, according to embodiments of the disclosure.

FIG. 5 is a functional block diagram illustrating an alternative embodiment of the test and measurement instrument illustrated in FIG. 4, according to embodiments of the disclosure.

### DESCRIPTION

Reducing the latency of generating a trigger out signal from a trigger in signal in a test and measurement instrument is possible, according to embodiments of the disclosure, by adding a low-latency trigger processing path in parallel to a standard trigger processing path. In some embodiments a user may select which trigger path is used to generate an output trigger signal of the instrument.

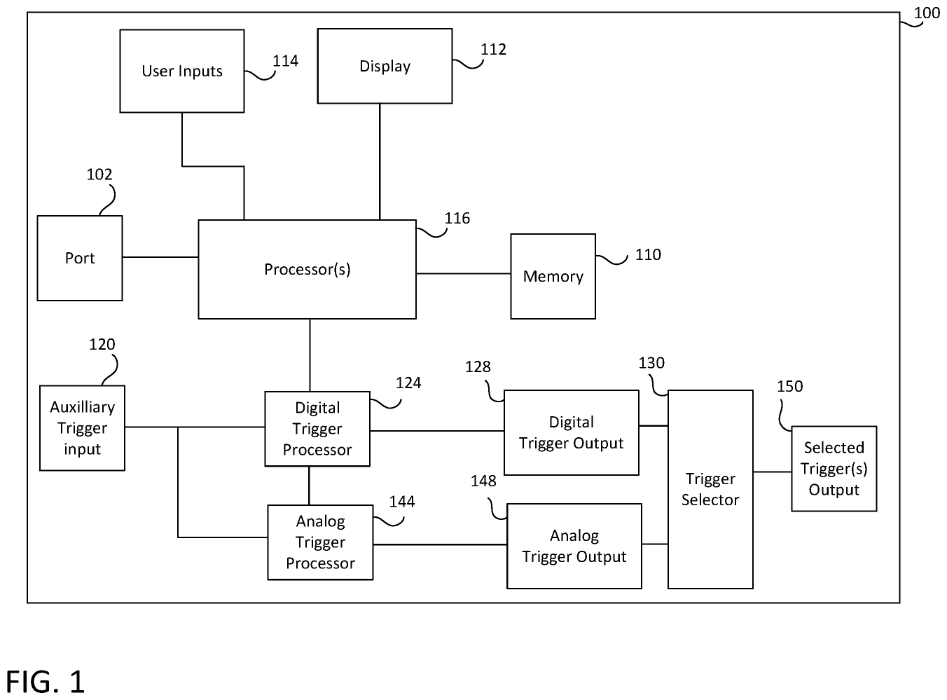

FIG. 1 is a block diagram of an example test and measurement instrument 100, such as an oscilloscope, for implementing embodiments of the disclosure disclosed herein. The test and measurement instrument 100 includes one or more ports 102, which may be any electrical signaling medium. The ports 102 may include receivers, transmitters, and/or transceivers. Each port 102 is a channel of the test and measurement instrument 100. The ports 102 are coupled with one or more processors 116 to process the signals and/or waveforms received at the ports 102 from one or more devices under test (DUTs). Although only one processor 116 is shown in FIG. 1 for ease of illustration, as will be understood by one skilled in the art, multiple processors 116 of varying types may be used in combination, rather than a single processor 116.

The ports 102 can also be connected to a measurement unit in the test instrument 100, which is not depicted for ease of illustration. Such a measurement unit can include any component capable of measuring aspects (e.g., voltage, amperage, amplitude, etc.) of a signal received via ports 102. The test and measurement instrument may include additional hardware and/or processors, such as conditioning circuits, analog to digital converters, and/or other circuitry to convert a received signal to a waveform for further analysis. The resulting waveform can then be stored in a memory 110, as well as displayed on a display 112.

The one or more processors 116 may be configured to execute instructions from memory 110 and may perform any methods and/or associated steps indicated by such instructions, such as displaying and modifying the input signals received by the instrument. Memory 110 may be implemented as processor cache, random access memory (RAM), read only memory (ROM), solid state memory, hard disk drive(s), or any other memory type. Memory 110 acts as a medium for storing data, computer program products, and other instructions.

User inputs 114 are coupled to the processor 116. User inputs 114 may include a keyboard, mouse, touchscreen, and/or any other controls employable by a user to set up and control the instrument 100. User inputs 114 may include a graphical user interface on the display 112. User inputs 114 may further include programmatic inputs from the user on the instrument 100, or from a remote device. The display 112 may be a digital screen, a cathode ray tube based display, or any other monitor to display waveforms, measurements, and other data to a user. While the components of test instrument 100 are depicted as being integrated within test and measurement instrument 100, it will be appreciated by a person of ordinary skill in the art that any of these components can be external to test instrument 100 and can be coupled to test instrument 100 in any conventional manner (e.g., wired and/or wireless communication media and/or mechanisms). For example, in some embodiments, the display 112 may be remote from the test and measurement instrument 100, or the instrument may be configured to send output to a remote device in addition to displaying it on the instrument 100. In further embodiments, output from the measurement instrument 100 may be sent to or stored in remote devices, such as cloud devices, that are accessible from other machines coupled to the cloud devices.

The test and measurement instrument 100 also includes an auxiliary trigger input 120 that is configured to receive a trigger signal generated by a device separate from the instrument 100. Typically the trigger signal is an analog signal that indicates a start time of a particular event of interest in the input signal received through one or more of the ports 102. The trigger signal may also indicate other events relevant to the instrument 100 and its test and measurement operations. A digital trigger processor 124 is coupled to the auxiliary trigger input port 120 to process the received trigger signal and create a digital trigger signal for use by the processor 116 to control operation of the instrument 100. A digital trigger output port 128 conveys the digitally processed trigger signal to an output. In a conventional device, the digital trigger output port 128 is the only trigger output from the instrument. In general, processing the trigger input signal received from the auxiliary trigger input 120 through the digital trigger processor 124 takes a relatively long time to process, on the order of 1-2 μs. In systems that cascade multiple instruments to one another, the processing time used by each of the digital trigger processors 124 in each of the devices is additive and causes the cascaded trigger delay described above, which is undesirable.

Embodiments according to the disclosure further include an analog trigger processor 144 that processes the trigger input signal from the auxiliary trigger input 120 to an analog trigger output 148 much quicker than the digital trigger processor 124 described above. For example, processing the trigger input signal from the auxiliary trigger input 120 to an analog trigger output 148 may incur delay of 35 ns, which is much faster than the 1-2 μs processing time for the digital trigger. In some embodiments, the processing time for processing the trigger input signal from the auxiliary trigger input 120 to an analog trigger output 148 may incur delay of between 20-50 ns, or even up to 100 ns, which is still faster than the digital trigger processing delay. After the analog trigger output 148 is generated, a user may select either the digital trigger output 128 or the analog trigger output as the selected trigger signal 150 that is output from the instrument, depending on the needs of the testing system. In some embodiments a selector 130 may be configured or operated by the user to select the desired trigger output. In some embodiments the selector 130 may be a multiplexer. In other embodiments the trigger selector 130 may accept programmatic inputs that may be configured by the user during setup of the instrument 100. In yet other embodiments, the user may select or configure the trigger selector 130 to output both of the digital trigger output 128 and the analog trigger output 148 in parallel, although the digital trigger output 128 may lag the analog trigger output 148 due to the longer time of processing the digital trigger output. In yet further embodiments, the trigger selector 130 may default to passing the digital trigger output 128 unless the user selects that the analog trigger output 148 be passed instead.

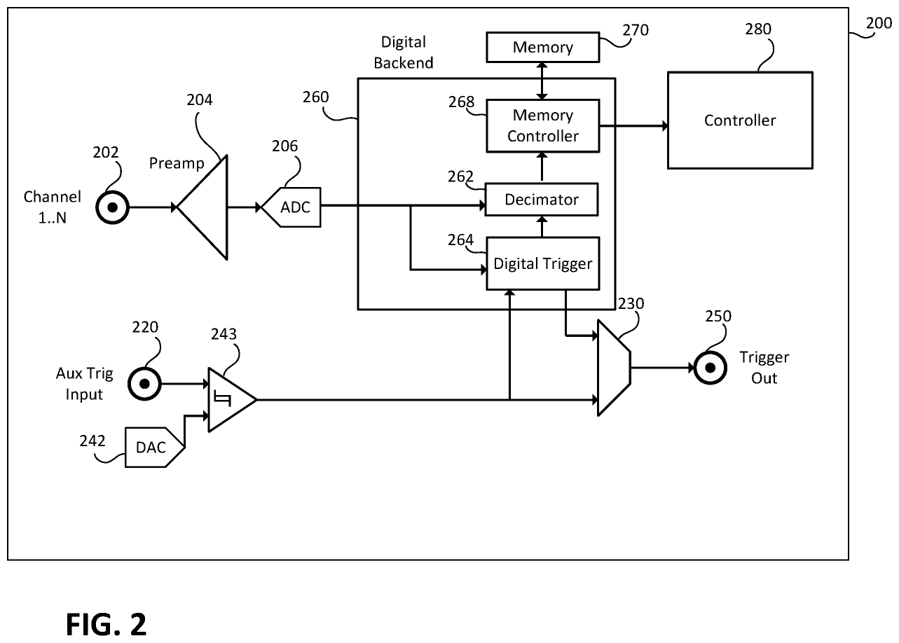

FIG. 2 is a functional block diagram illustrating another representation of an instrument 200 having parallel trigger paths according to embodiments of the disclosure. The functional blocks represented in FIG. 2 may relate to functional blocks described with reference to FIG. 1 as described below. In general, the instrument 200 includes one or more input ports 202, each of which may represent a channel of the instrument 200. Each of the input ports 202 may optionally be coupled to a preamplifier 204 and optionally to an Analog to Digital Converter (ADC) 206. The instrument 200 also includes an auxiliary trigger input 220 to signal the beginning of a point of interest of the input signal received on one or more of the input ports 202, or other signal relevant to the operation of the instrument 200. The trigger signal from the auxiliary trigger input 220 may be evaluated by a comparator 243, which accepts the trigger signal input from the trigger input 220 as well as from a Digital to Analog Converter (DAC) 242. The comparator uses an input value from the DAC 242 to establish a threshold to compare against the trigger signal. The value produced by the DAC 242 may be user selectable and related to a desired trigger signal level. When the trigger signal level exceeds, or, in some cases, is less than, the value received from the DAC 242, the comparator 243 outputs or passes the trigger signal as its output.

A digital backend 260 receives input from the ADC 206, containing the input signal of interest for test and measurement, as well as an input from the comparator 243, which indicates that an appropriate trigger signal has been received on the auxiliary trigger input 220. In general, the digital backend 260 processes the input signal from the ADC 206 according to its programmed operation. Some or all of the functions of the digital backend 260 may be performed by, for example, the processor 116 of FIG. 1. The digital backend 260 may include a decimator 262 to establish a sampling rate of the input signal, and may further include a memory controller 268 to cause the sampled input signal to be stored as an input waveform in a memory 270. The digital backend 260 may include a digital trigger processor 264, which operates as described above. Output or control signals from the digital backend 260 may be sent to a controller 280, which operates the instrument 200 to execute one or more test and measurement functions on the input waveform stored in the memory 270, or on other waveforms. The controller 280 may include one or more processors, such as the processor 116 of FIG. 1. Further, some or all of the processing of the digital backend 260 may be performed by the processor 116 of FIG. 1, or other appropriately configured processors in a test and measurement device.

A selector 230, which may be a multiplexer, operates as the trigger selector 130 described above. The selector 230 receives inputs from both the analog trigger signal from the comparator 243 as well as a digital trigger that was generated by the digital signal processor 264. As described above, the user controls the selector 230 to determine which of the digital trigger or the analog trigger, or both, is output by the instrument 200 at a trigger output 250. The user may also control whether the analog or digital trigger is used by the instrument 200 to control operation of the instrument. For example, the user may specify that either the analog trigger or the digital trigger will be used by the instrument 200 to stop acquisition of the present waveform. The user control may be communicated to the instrument 200 through the user inputs 114 of FIG. 1, which may be programmatic inputs or inputs through a user interface. Although not separately illustrated, the instrument 200 may include buffers, amplifiers, or other circuitry to condition the trigger signal output at the trigger output 250 for use by other instruments downstream.

Using the systems described with reference to FIGS. 1 and 2, the user can select either an analog trigger output, derived from the auxiliary trigger input 120 or 220, or a digital trigger output, generated by the digital trigger processor 124 or 264, or both, as the respective trigger outputs of the instruments 100, 200. Even in systems where the user selects the analog trigger signal as the output signal of an instrument, the instrument itself will preferably use the digital trigger generated by the digital trigger processor 124 or 264, as the triggering signal for use by the local instrument. By selecting the analog trigger out, however, in test systems having multiple cascaded devices each using one of the cascaded triggers from the preceding device, the overall latency of such a system is greatly reduced compared to present day systems, because the analog trigger path through an instrument is much faster than the digital trigger path, as described above.

One potential downside to the embodiment illustrated in FIG. 2 is that, when the analog trigger signal from the comparator 243 is selected as the trigger out 250, the analog trigger out signal of the instrument 200 will just match the pulse width and polarity of the auxiliary trigger in received at the auxiliary trigger input 220. It may be beneficial to modify the analog trigger signal somewhat to provide a consistent pulse width and direction for the trigger out signal, regardless of which polarity the edge trigger is set to.

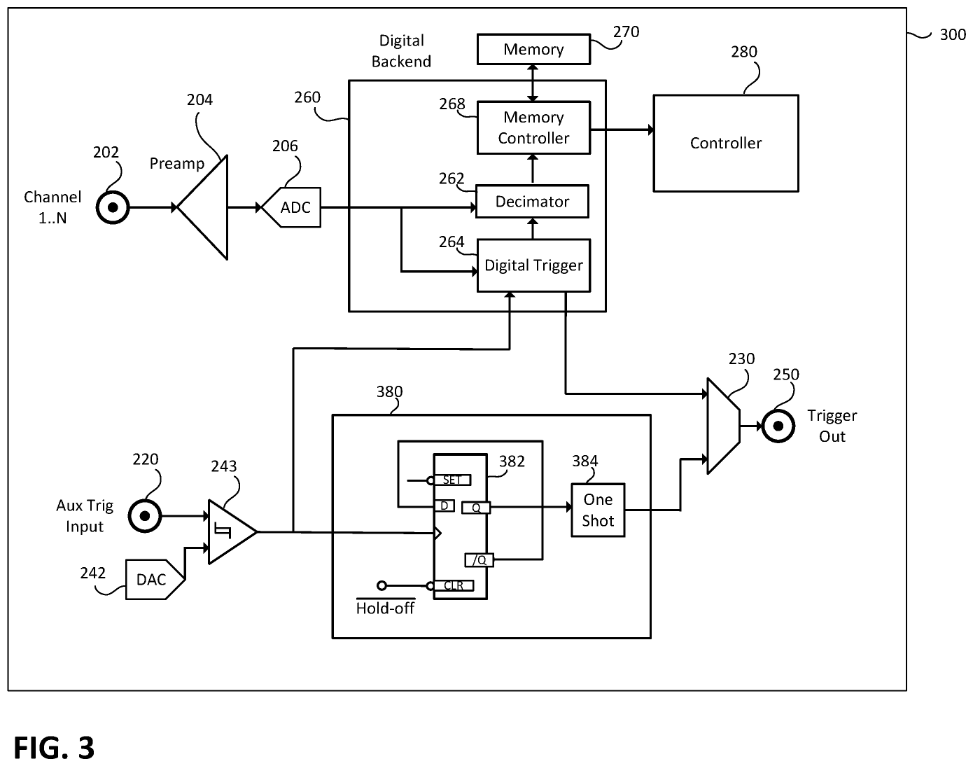

FIG. 3 is a functional block diagram of a test and measurement instrument 300 including an analog trigger conditioning circuit 380. Many of the components of the test and measurement instrument 300 are the same or similar to the test and measurement instrument 200 described with reference to FIG. 2, and are not described again, for brevity. The analog trigger conditioning circuit 380 may be embodied in a Field Programmable Gate Array (FPGA), an Application Specific Integrated Circuit (ASIC), a specifically programmed general or specific processor, discrete components, or by a combination of one or more of these devices.

The analog trigger conditioning circuit 380 includes a latch or flip-flop, such as the latch 382, as well as a one-shot circuit 384, which operate as described below. In general, the analog trigger conditioning circuit 380 operates as a filter and edge-triggered pulse generator configured to modify the analog trigger signal received at the auxiliary trigger input 220 to an output analog trigger signal having desired shape and polarity. Desired shape of the output analog trigger signal includes both pulse width, pulse amplitude, and pulse duration. Polarity of the output analog trigger signal may be controlled by selecting a desired one of the two outputs of the latch 382, which are inverse to one another.

The latch 382 further includes a Holdoff input that operates to prevent the latch 382 from generating a signal while the Holdoff input is asserted. The Holdoff input may be positive or negative logic depending on implementation. In general, a Holdoff signal is generated when the operator of the instrument 300 wishes to prevent the instrument from taking another acquisition of the input signal. A user may also control the Holdoff signal to increase space between adjacent acquisitions to a certain, predetermined, amount, or to keep acquisitions from synchronizing with the device being tested. The logic in the analog trigger conditioning circuit 380 can be constrained either to minimal clock cycles or may be run asynchronous to avoid the latency of the normal digital trigger system, such as caused by the digital trigger processor 264.

In the illustrated embodiment, the analog trigger signal from the comparator 243 is presented to a clock input of the latch 382. The analog trigger signal from the comparator 243 is also presented to the digital trigger processor 264 so that the instrument 300 may generate a digital trigger for use by the instrument, as described above. When the Holdoff signal is de-asserted, and when the comparator 243 outputs a qualified analog trigger signal, the latch 382 generates an output signal on either of its outputs, which are inverted from one another. Depending on which polarity the user prefers, the selected output signal from the latch 382 is presented to a one-shot circuit 384, which generates an output pulse having a pre-selected duration, amplitude, and polarity. This output signal from the one-shot circuit 384 becomes the analog trigger signal that has been filtered from the analog trigger signal from the auxiliary trigger input 220, as described above. Also as described above, the user may control, by using the selector 230, whether the filtered analog output pulse from the one-shot circuit 384 or the digital trigger produced by the digital trigger processor 264 is to be sent to the trigger output 250 of the instrument 300.

In the instrument 300, the output of the comparator 243 is one input to the digital trigger processor 264, but the digital trigger processor may include dozens or even hundreds of other potential trigger inputs based on other triggering events. These other potential trigger inputs to the digital trigger processor 264 may be controlled by software and modified by the user based on the desired triggering conditions.

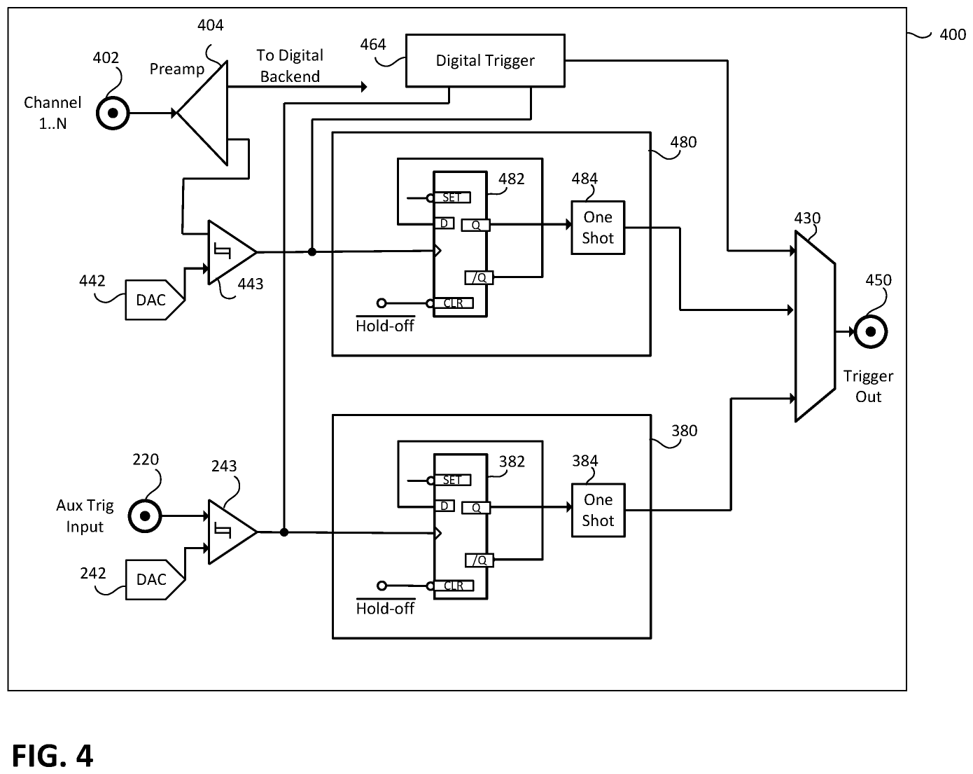

FIG. 4 is a functional block diagram of a test and measurement instrument 400 including an analog trigger conditioning circuit 380 as well as a second triggering unit that uses an acquired input signal condition to generate a trigger from the input signal. In the test and measurement instrument 400, the auxiliary trigger system described above with reference to FIG. 3, including the auxiliary trigger input 220, DAC 242, comparator 243 and analog trigger conditioning circuit 380, operate the same or similar to the system described above. The test and measurement instrument 400 further includes an input trigger conditioning circuit 480 that operates based on a condition evaluated from an input signal received on one or more input ports 402. The test and measurement instrument 400 also includes the other components illustrated in FIGS. 2 and 3, such as the digital backend 260, and controller 280, which have been omitted for clarity.

As described above, in addition to the auxiliary trigger received on the auxiliary trigger input 220, the test and measurement instrument 400 may generate triggers based on conditions of the test signal as it is being acquired. A preamplifier 404 generally buffers or amplifies the input signal from one of the input ports 402, and sends its output to a digital backend, as described above. The test and measurement instrument 400, further includes, however, the input trigger conditioning circuit 480 that functions to generate a trigger signal from the acquired input signal. In practice, the amplified input signal is output from the preamplifier 404 to a comparator 443. The comparator 443 operates similar to the comparator 243, described above, to generate a trigger signal from the input signal when the input signal exceeds, or fails to exceed, a threshold set by a DAC 442. Then, the trigger signal from the comparator 443 operates similar to the signal generated by the comparator 243. For instance, the input trigger conditioning circuit 480 generates an output pulse at the one-shot circuit 484 when a satisfying trigger pulse is received at a latch 482. The output from the comparator 443 is presented to the digital trigger 464, which also receives input from the comparator 243 if an auxiliary trigger signal is detected at the auxiliary trigger input 220. The digital trigger processor 464 generates a digital trigger based on either of the auxiliary trigger signal from the comparator 243 or an input signal trigger from the comparator 443. A selector 430, such as a multiplexer, may be used to select any of the conditioned analog trigger, conditioned input trigger, or a digital trigger from the digital trigger processor 464. In some embodiments any of the digital trigger 464 or the digital trigger 264 described above may also include conditioning circuits, such as the input trigger conditioning circuit 480 or the auxiliary analog trigger conditioning circuit 380, to generate a specific output pulse to indicate that a trigger event has occurred.

By including inputs to receive both the auxiliary trigger signal from the comparator 243 and the input signal trigger from the comparator 443, the test and measurement instrument 400 ensures that an acquisition of the input test signal on the port 402 occurs even if the digital trigger system misses a trigger that the analog trigger system detected. In one embodiment, a timer (not illustrated in FIG. 4) is started in the digital trigger processor 464 when the analog trigger is received from the comparator 243, and a trigger is forced when the timer exceeds a time set by characterizing the system.

Although only one input signal trigger system is illustrated in FIG. 4, embodiments of the invention may include multiple, independent, input signal trigger systems, each set to trigger on various conditions of the input signal. These conditions are predetermined by the user when setting up the instrument 400 for operation.

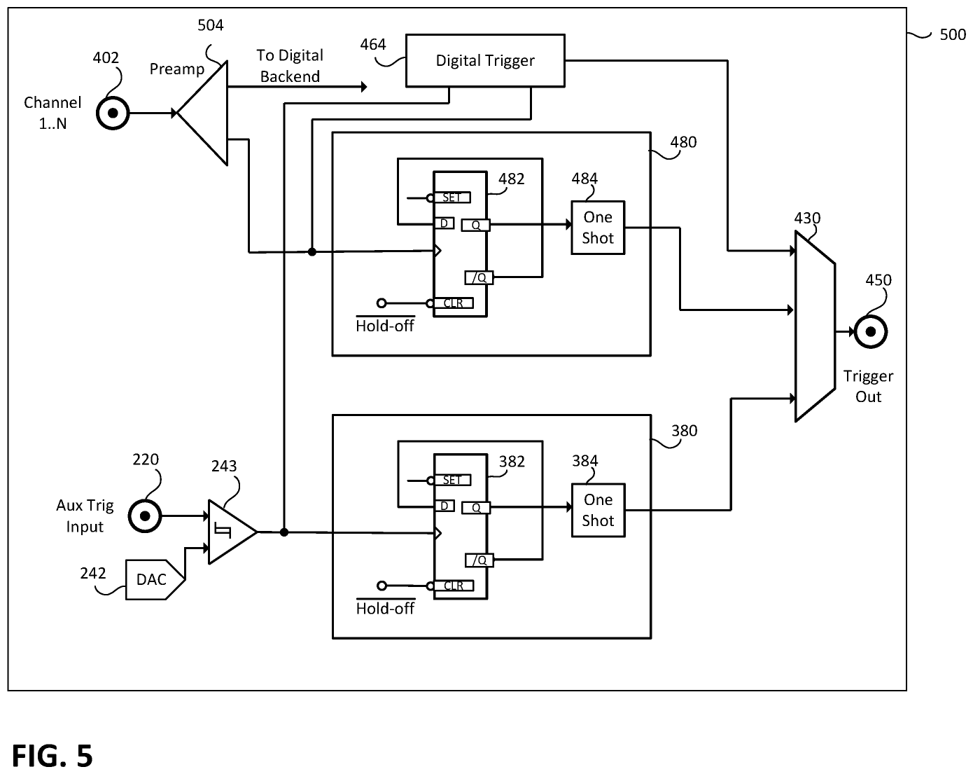

At some bandwidth of an oscilloscope channel, including a discrete comparator, such as the comparator 443, isn't feasible due to the high acquisition speeds, such as in excess of 100 GHz. FIG. 5 illustrates a test and measurement instrument 500 in which an analog trigger comparator is integrated into a preamplifier 504. A DAC, such as the DAC 442 of FIG. 4 may be integrated with the comparator in the preamplifier 504, or may be embodied in a separate device. In yet other embodiments, the input trigger conditioning circuit 480, or portions thereof, may also be integrated into the preamplifier 504.

Using embodiments according to the disclosure described above, a user can select which of the available triggers are output from a test and measurement instrument. In some embodiments the user may choose to pass an auxiliary trigger signal received on an auxiliary trigger input directly through the instrument to an auxiliary trigger output. This configuration passes the auxiliary trigger in the quickest way possible, while still providing the local machine with an ability to generate a digital trigger from the analog auxiliary trigger. The trigger signal received from the auxiliary trigger input may have lower, and in some cases, much lower, bandwidth than a test signal received on an input port of the measurement instrument. In other embodiments the analog trigger signal from the auxiliary trigger input may be conditioned, such as with a standard pulse width, height, and polarity before sending it from the measurement instrument. In other embodiments triggers may be generated based on incoming test signals received on the input ports. In those embodiments a trigger signal may also be conditioned before being selected as the trigger output from the instrument. In yet other embodiments a digital trigger generated by the instrument from either the auxiliary trigger input or from the incoming test signals may be chosen to be the selected trigger output of the instrument.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the technologies disclosed herein are provided below. A configuration of the technologies may include any one or more, and any combination of, the examples described below.

Example 1 is a test and measurement instrument, including an auxiliary trigger input port for receiving an auxiliary trigger signal, a digital trigger processor for generating a digital trigger signal from the auxiliary trigger signal within a first processing time, an analog trigger processor for generating an analog trigger signal from the auxiliary trigger signal within a second processing time that is faster than the first processing time, and a user-configurable selector coupled to the digital trigger processor and to the analog trigger processor, the user-configurable selector configured to output either the digital trigger signal or the analog trigger signal as a selected trigger output signal of the instrument.

Example 2 is a test and measurement instrument according to Example 1, further comprising an input channel for accepting an input signal for analysis by the instrument.

Example 3 is a test and measurement instrument according to Example 2, further comprising an input through which a user may cause the instrument to use a selected one of the analog trigger signal or the digital trigger signal to control an acquisition of the input signal.

Example 4 is a test and measurement instrument according to any of the preceding Examples, in which the analog trigger processor includes a comparator structured to receive the auxiliary trigger signal and pass an output signal only when the received auxiliary trigger signal exceeds a predetermined threshold.

Example 5 is a test and measurement instrument according to Example 4, in which the analog trigger processor includes a pulse conditioning circuit.

Example 6 is a test and measurement instrument according to Example 5, in which the pulse conditioning circuit includes a hold off input, and in which the pulse conditioning circuit refrains from generating an output when the hold off input is asserted.

Example 7 is a test and measurement instrument according to Example 5, in which the pulse conditioning circuit accepts an input signal derived from the auxiliary trigger signal and generates an output signal having a predefined shape.

Example 8 is a test and measurement instrument according to Example 7, in which the output signal has a predefined amplitude, width, or polarity.

Example 9 is a test and measurement instrument according to Example 2, in which the digital trigger processor is structured to generate a second digital trigger signal based on conditions of the input signal received on the input channel.

Example 10 is a test and measurement instrument according to Example 9, in which the conditions of the input signal to cause the generation of the second digital trigger signal are user defined.

Example 11 is a test and measurement instrument according to any of the preceding Examples, in which the digital trigger processor a hold off input, and in which the digital trigger processor refrains from generating an output when the hold off input is asserted.

Example 12 is a method of generating trigger signals in a test and measurement instrument, including accepting an input signal at an input port for evaluation, accepting an auxiliary trigger signal at a trigger port, generating a digital trigger signal from the auxiliary trigger signal, generating an analog trigger signal from the auxiliary trigger signal, accepting a trigger selection from a user, and passing the digital trigger signal or the analog trigger signal as an output of the test and measurement device, depending on the trigger selection.

Example 13 is a method of generating trigger signals in a test and measurement instrument according to Example 12, in which generating an analog trigger signal from the auxiliary trigger signal comprises comparing the auxiliary trigger signal to a predetermined threshold and passing the analog trigger signal only when the received auxiliary trigger signal exceeds the predetermined threshold.

Example 14 is a method of generating trigger signals in a test and measurement instrument according to Example 13 further comprising conditioning the analog trigger signal through a conditioning circuit.

Example 15 is a method of generating trigger signals in a test and measurement instrument according to Example 14, in which conditioning the analog trigger signal through a conditioning circuit comprises suspending a generation of the analog trigger signal while a hold off input is asserted.

Example 16 is a method of generating trigger signals in a test and measurement instrument according to Example 14 in which conditioning the analog trigger signal through a conditioning circuit comprises generating an analog trigger signal having a predefined shape.

Example 17 is a method of generating trigger signals in a test and measurement instrument according to Example 16, in which the analog trigger signal has a predefined amplitude, width, or polarity.

Example 18 is a method of generating trigger signals in a test and measurement instrument according to any of the preceding Example methods, further comprising generating a second digital trigger signal based on conditions of the input signal received on the input channel.

Example 19 is a method of generating trigger signals in a test and measurement instrument according to Example 18, in which generating a second digital trigger signal based on conditions includes generating the second digital trigger signal based on user-defined conditions.

Example 20 is a method of generating trigger signals in a test and measurement instrument according to any of the preceding Example methods, in which generating a digital trigger signal from the auxiliary trigger signal comprises suspending a generation of the digital trigger signal while a hold off input is asserted.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although specific aspects of the disclosure have been illustrated and described for purposes of illustration, it will be understood that various modifications may be made without departing from the spirit and scope of the disclosure. Accordingly, the disclosure should not be limited except as by the appended claims.

We claim:

1. A test and measurement instrument, comprising:
an auxiliary trigger input port for receiving an auxiliary trigger signal;
a digital trigger processor for generating a digital trigger signal from the auxiliary trigger signal within a first processing time;
an analog trigger processor for generating an analog trigger signal from the auxiliary trigger signal within a second processing time that is faster than the first processing time; and
a user-configurable selector coupled to the digital trigger processor and to the analog trigger processor, the user-configurable selector configured to output either the digital trigger signal or the analog trigger signal as a selected trigger output signal of the instrument.

2. The test and measurement instrument according to claim 1, further comprising an input channel for accepting an input signal for analysis by the instrument.

3. The test and measurement instrument according to claim 2, further comprising an input through which a user may cause the instrument to use a selected one of the analog trigger signal or the digital trigger signal to control an acquisition of the input signal.

4. The test and measurement instrument according to claim 1, in which the analog trigger processor includes a comparator structured to receive the auxiliary trigger signal and pass an output signal only when the received auxiliary trigger signal exceeds a predetermined threshold.

5. The test and measurement instrument according to claim 4, in which the analog trigger processor includes a pulse conditioning circuit.

6. The test and measurement instrument according to claim 5, in which the pulse conditioning circuit includes a hold off input, and in which the pulse conditioning circuit refrains from generating an output when the hold off input is asserted.

7. The test and measurement instrument according to claim 5, in which the pulse conditioning circuit accepts an input signal derived from the auxiliary trigger signal and generates an output signal having a predefined shape.

8. The test and measurement instrument according to claim 7, in which the output signal has a predefined amplitude, width, or polarity.

9. The test and measurement instrument according to claim 2, in which the digital trigger processor is structured to generate a second digital trigger signal based on conditions of the input signal received on the input channel.

10. The test and measurement instrument according to claim 9, in which the conditions of the input signal to cause the generation of the second digital trigger signal are user defined.

11. The test and measurement instrument according to claim 1, in which the digital trigger processor a hold off input, and in which the digital trigger processor refrains from generating an output when the hold off input is asserted.

12. A method of generating trigger signals in a test and measurement instrument, the method comprising:
accepting an input signal at an input port for evaluation;
accepting an auxiliary trigger signal at a trigger port;
generating a digital trigger signal from the auxiliary trigger signal;
generating an analog trigger signal from the auxiliary trigger signal;
accepting a trigger selection from a user; and
passing the digital trigger signal or the analog trigger signal as an output of the test and measurement device, depending on the trigger selection.

13. The method of generating trigger signals in a test and measurement instrument according to claim 12, in which generating an analog trigger signal from the auxiliary trigger signal comprises comparing the auxiliary trigger signal to a predetermined threshold and passing the analog trigger signal only when the received auxiliary trigger signal exceeds the predetermined threshold.

14. The method of generating trigger signals in a test and measurement instrument according to claim 13, further comprising conditioning the analog trigger signal through a conditioning circuit.

15. The method of generating trigger signals in a test and measurement instrument according to claim 14, in which conditioning the analog trigger signal through a conditioning circuit comprises suspending a generation of the analog trigger signal while a hold off input is asserted.

16. The method of generating trigger signals in a test and measurement instrument according to claim 14, in which conditioning the analog trigger signal through a conditioning circuit comprises generating an analog trigger signal having a predefined shape.

17. The method of generating trigger signals in a test and measurement instrument according to claim 16, in which the analog trigger signal has a predefined amplitude, width, or polarity.

18. The method of generating trigger signals in a test and measurement instrument according to claim 12, further comprising generating a second digital trigger signal based on conditions of the input signal received on the input channel.

19. The method of generating trigger signals in a test and measurement instrument according to claim 18 in which generating a second digital trigger signal based on conditions includes generating the second digital trigger signal based on user-defined conditions.

20. The method of generating trigger signals in a test and measurement instrument according to claim 12, in which generating a digital trigger signal from the auxiliary trigger signal comprises suspending a generation of the digital trigger signal while a hold off input is asserted.
